(19) United States
(12) Patent Application Publication
(10) Pub. No.: US 2008/0156520 A1
(43) Pub. Date: Jul. 3, 2008

(54) Complex printed circuit board structure

(75) Inventors: Chang-Liang Lin, Tainan City (TW); Chi-Lung Lee, Tainan City (TW); Hui-Yuan Liang, Tainan City (TW); Jiu-Yan Yan, Tainan City (TW)

Correspondence Address: BACON & THOMAS, PLLC, 625 SLATERS LANE, FOURTH FLOOR, ALEXANDRIA, VA, 22314, US

(73) Assignee: Bothhand Enterprise Inc., Tainan City (TW)

(21) Appl. No.: 12/005,308

(22) Filed: Dec. 27, 2007

(30) Foreign Application Priority Data
Dec. 29, 2006 (TW) 095223110

(51) Int. Cl. H05K 1/03

(52) U.S. Cl. 174/252

(57) ABSTRACT

A complex printed circuit board structure including a flexible printed wiring board and a heat-dissipating substrate bonded with the flexible printed wiring board. Parts of surface material of the flexible printed wiring board is removed to form depressions or through holes for laying electronic elements therein. The surfaces of the electronic elements can at least partially get closer to or directly contact the heat-dissipating substrate through the depressions or through holes of the flexible printed wiring board. Therefore, the heat generated by the electronic elements can be more quickly and directly conducted to the heat-dissipating substrate and dissipated at high efficiency.

### BACKGROUND OF THE INVENTION

The present invention is related to an improved complex printed circuit board, and more particularly to a complex printed circuit board which is able to quickly dissipate the heat generated inside the electronic elements from the heat-dissipating substrate at high efficiency.

FIG. 1 shows a conventional flexible printed circuit board adapted to various configurations of the existent electronic products. The electronic elements 30 with conductive sections 32 are arranged on the flexible printed wiring board 1 in predetermined positions. Then the printed wiring board 1 is laid on and combined with a heat-radiating substrate 2 for enhancing heat-radiation effect. That is, the heat-radiating substrate 2 is laid on the other face of the flexible printed wiring board 1 opposite to the electronic elements 30 for dissipating the heat produced in operation of the electronic elements 30. The heat-radiating substrate 2 is made of a material with good thermal conductivity, such as aluminum, copper or an alloy material. In general, the heat-radiating substrate 2 is a rigid board. Therefore, when combined with the flexible printed wiring board 1 with quite different performances, a bonding layer 21 is disposed between the flexible printed wiring board 1 and the heat-radiating substrate 2 for effectively bonding these two boards.

Referring to FIG. 2, when the electronic element 30 such as a high-power light-emitting diode works, a considerable amount of heat will be produced inside. The heat must be quickly dissipated for maintaining normal operation of the device. The top of the electronic element 30 is isolated from outer side due to the packaging material 33 so that most of the heat is dissipated in the directions of arrows as shown in FIG. 2. In effect, the heat inside the main body 31 of the electronic element 30 is rarely directly dissipated through the air. Therefore, most of the heat is first conducted from the main body 31 to the flexible printed wiring board 1 via the conductive section 32. Then the heat goes through the bonding layer 21 to the heat-radiating substrate 2. The remaining heat is conducted from the bottom of the main body 31 to the flexible printed wiring board 1. This part of heat also goes through the bonding layer 21 to the heat-radiating substrate 2.

According to the above heat-radiating mode, the heat is conducted to the heat-radiating board 2 through the flexible printed wiring board 1 which has relatively poor thermal conductivity. As a result, the heat-dissipating effect is limited and not ideal, especially in a field employing many high-power electronic elements 30. Under such circumstance, the number of the electronic elements per unit are a must be restricted so as to avoid damage of the circuit or device due to overheating. This seriously affects the development of configuration of the product. It is therefore tried by the applicant to redesign the complex printed circuit board to achieve better heat-radiating effect and reserve more mobile design space for the product.

### SUMMARY OF THE INVENTION

It is therefore a primary object of the present invention to provide an improved complex printed circuit board which is able to quickly dissipate the heat generated by the electronic elements at high efficiency. Therefore, more electronic elements can be arranged in unit area of the complex printed circuit board.

According to the above object, the complex printed circuit board structure of the present invention includes a flexible printed wiring board and a heat-dissipating substrate bonded with the flexible printed wiring board. At least one electronic circuit is connected with the flexible printed wiring board. Parts of the surface material of the flexible printed wiring board is removed to form depressions or through holes in which the electronic elements are disposed. Therefore, the surface of the electronic element can at least partially get closer to or directly contact the heat-dissipating substrate through the depression or the through hole of the flexible printed wiring board. Accordingly, the heat generated inside the electronic element can be more quickly or directly conducted to the heat-dissipating substrate and dissipated at high efficiency.

The present invention can be best understood through the following description and accompanying drawings wherein:

### BRIEF DESCRIPTION OF THE DRAWINGS

FIG. 1 is a perspective view of a conventional complex printed circuit board;

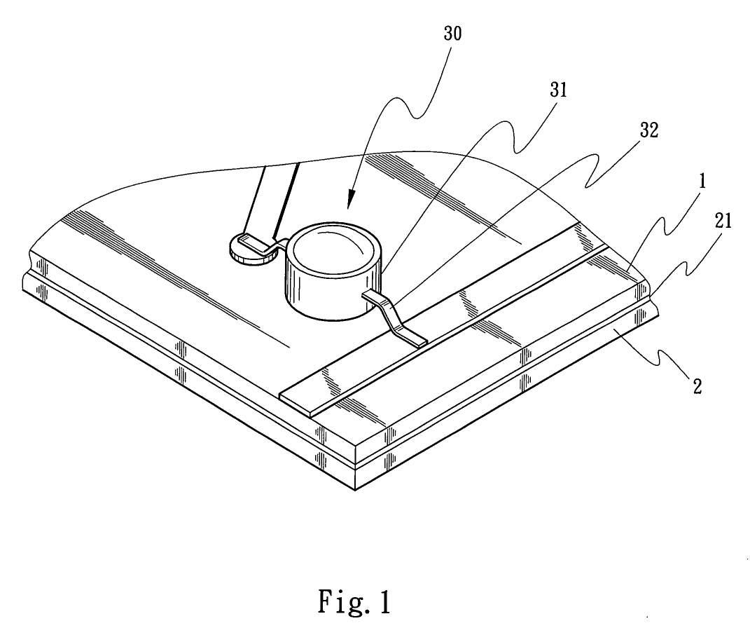

FIG. 2 is a sectional view according to FIG. 1;

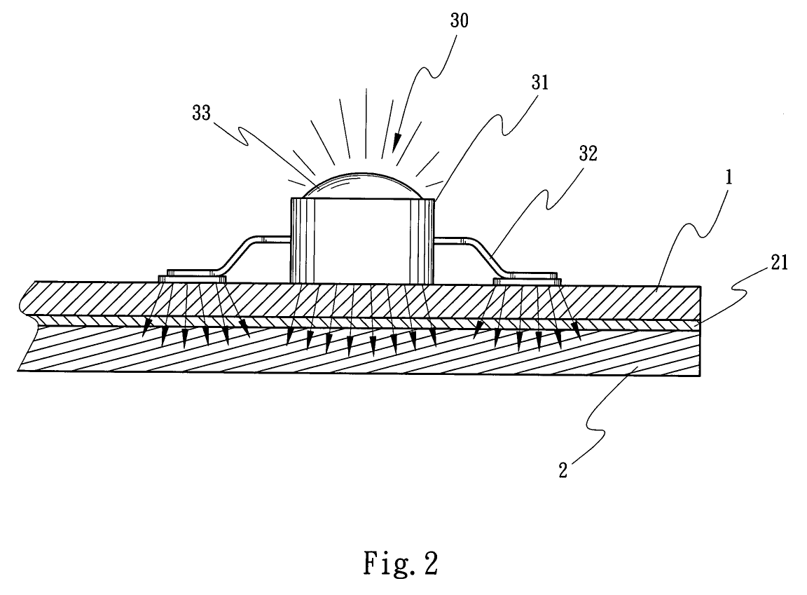

FIG. 3 is a perspective view of the complex printed circuit board of the present invention;

FIG. 4 is a sectional view according to FIG. 3, showing that the flexible printed wiring board is formed with depressions;

FIG. 4A is a sectional view according to FIG. 3, showing that the flexible printed wiring board is formed with through holes;

FIG. 5 is a perspective view of the complex printed circuit board of the present invention in an arced pattern; and

FIG. 6 shows that multiple electronic chips are directly implanted in the depression or the through hole of the flexible printed wiring board of the present invention.

### DETAILED DESCRIPTION OF THE PREFERRED EMBODIMENTS

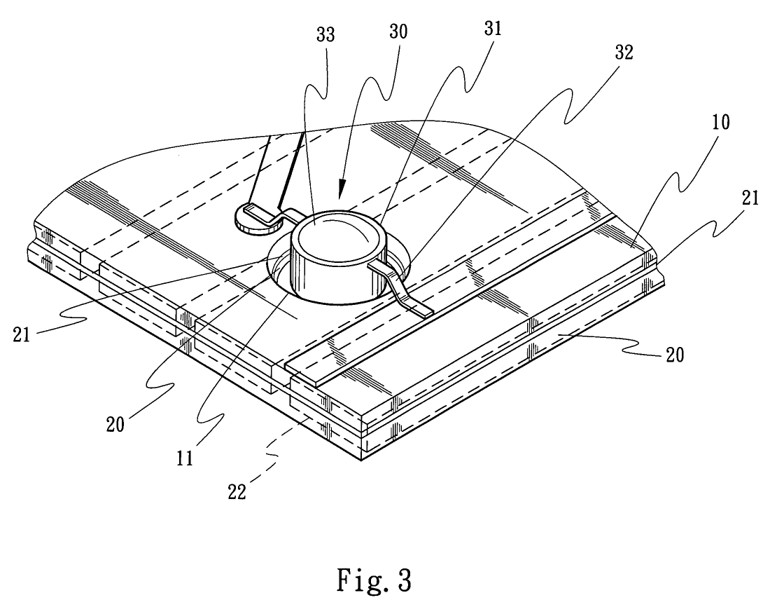

Please refer to FIG. 3. According to a preferred embodiment, the complex printed circuit board structure of the present invention includes a flexible printed wiring board 10 and a heat-dissipating substrate 20 bonded with the flexible printed wiring board 10. Electronic circuits are laid on the flexible printed wiring board 10. The heat-dissipating substrate 20 serves to conduct and dissipate the heat generated during working of the flexible printed wiring board 10. Specially, parts of the surface material of the flexible printed wiring board 10 is removed to form depressions 11 or through holes 11A or similar open areas in which the electronic elements 30 (powerful electronic elements likely to generate heat in working) are disposed. Therefore, the surface of the electronic element 30 can at least partially get closer to or directly contact the surface of the heat-dissipating substrate 20 through the depression 11 or through hole 11A of the flexible printed wiring board 10. Accordingly, the heat generated by the electronic element 30 can be more quickly and easily or directly conducted to the heat-dissipating substrate 20. As a result, the heat inside the electronic element 30 can be dissipated at high efficiency.

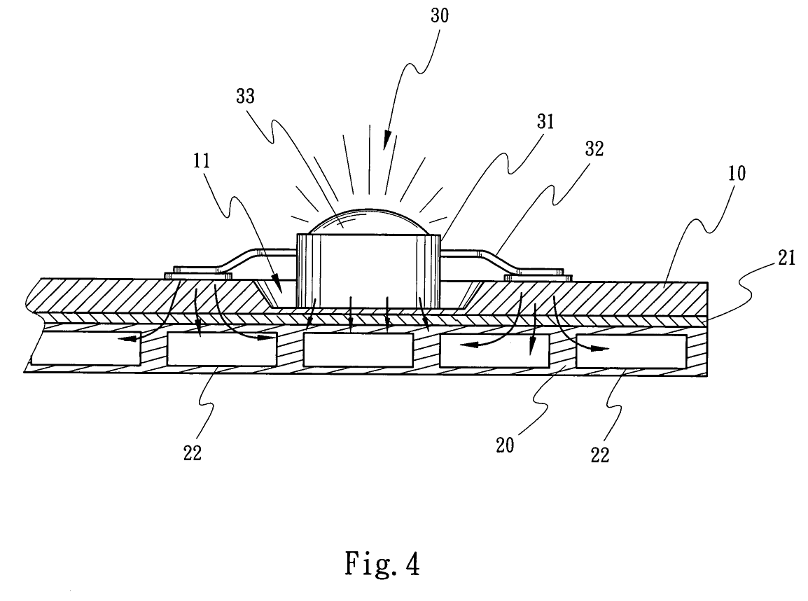

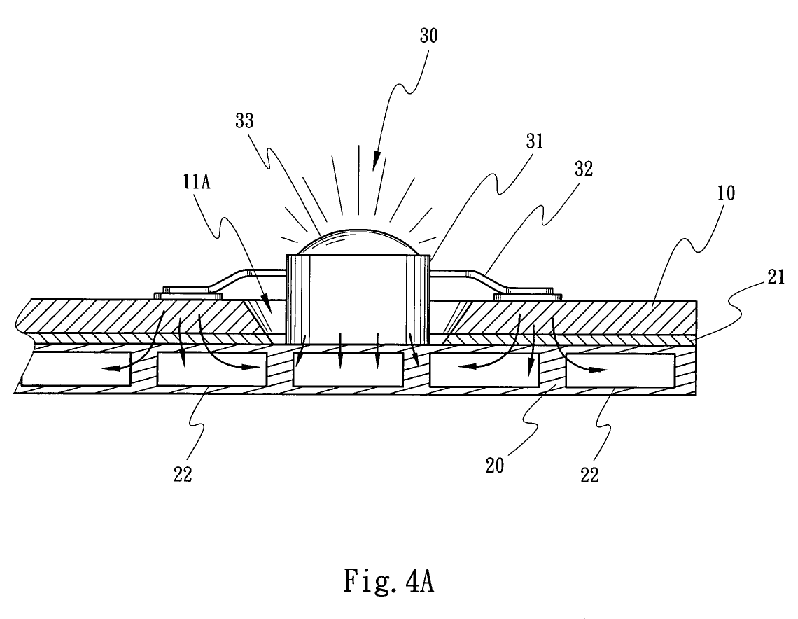

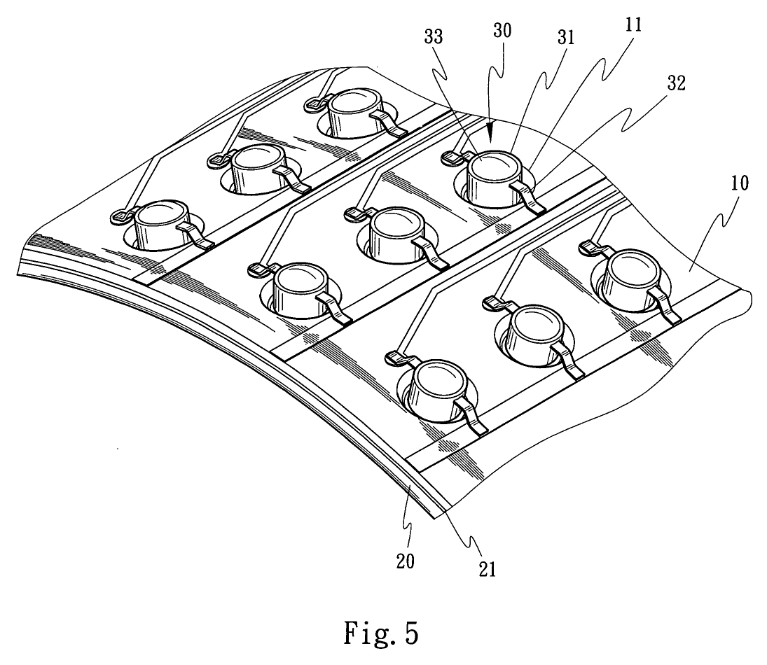

Referring to FIGS. 4 and 4A, the conductive section 32 of the electronic element 30 is a contact pin electrically connected with the circuit laid on the flexible printed wiring board 10. The bottom face of the main body 31 of the electronic element 30 is close to or directly contacts the heat-dissipating substrate 20 through the depression 11 or the through hole 11A of the flexible printed wiring board 10. In the case that the electronic element 30 is a high-power light-emitting diode, in working, the electronic element 30 will generate a lot of heat inside the main body 31. Under such circumstance, in a general heat-dissipating path, the heat can be conducted through the conductive section 32 to the flexible printed wiring board 10 and then conducted through the bonding layer 21 to the heat-dissipating substrate 20 and dissipated. In addition, in the shortened paths as shown by the arrows, the heat generated inside the electronic element 30 can be more quickly and directly conducted from the main body 31 to the heat-dissipating substrate 20 and dissipated. It should be noted that through the through hole 11A, when conducting the heat outside from the main body 31, it is unnecessary for the heat to go through the conductive section 31, the flexible printed wiring board 10 and the bonding layer 21. Therefore, the thermal resistance during the heat-dissipating procedure is greatly reduced so that the heat-dissipating effect is greatly enhanced. Furthermore, the heat-dissipating substrate 20 can have various configurations adapted to the changeable profile of the flexible printed wiring board 10. For example, as shown in FIGS. 3 and 4, the heat-dissipating substrate 20 has a pattern of flat board. As shown in FIG. 5, the heat-dissipating substrate 20 is an arced board. Moreover, the entire heat-dissipating substrate 20 can be formed with a cylindrical shape enclosed by the flexible printed wiring board 10. In addition, multiple heat pipes 22 can be arranged in the heat-dissipating substrate 20 side by side to fully enhance the heat-dissipating efficiency of the heat-dissipating substrate 20 and widen the application range thereof.

FIG. 5 shows that the heat-dissipating substrate 20 has an arced profile adapted to the configuration of the flexible printed wiring board 10. For example, the heat-dissipating substrate 20 can have a cylindrical configuration or a waved configuration. In addition, in case of a lot of high-power electronic elements 30, with the better heat-radiation efficiency of the present invention, more electronic elements 30 can be arranged in unit area. For example, the present invention is applicable to electronic sign, wall decorative lamp, etc.

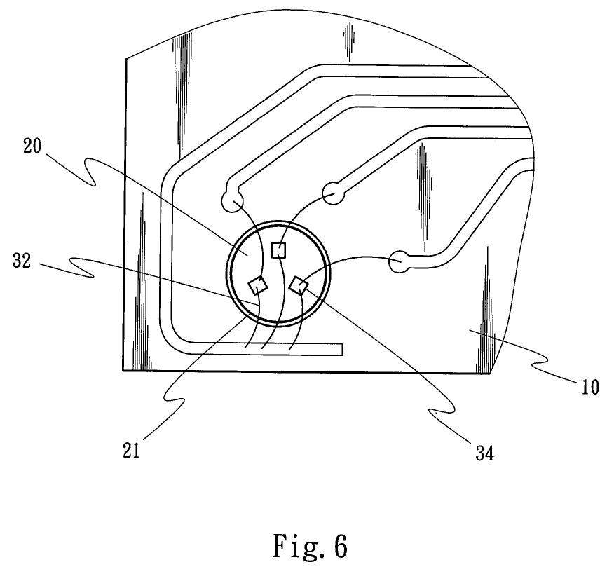

FIG. 6 shows another embodiment of the present invention, in which at least one high heat-generating electronic chip 34 (such as a light-emitting chip or a power crystal) is positioned in the depression 11 or through hole 11A. The electronic chip 34 is first fixedly disposed on the bottom of the depression 11 or the through hole 11A by way of adhesion or any other suitable measure. Then the electronic chip 34 is electrically connected to the circuit of the flexible printed wiring board 10 via a conductive section 32 which is a lead. Then the area of the depression 11 or the through hole 11A is packaged.

In conclusion, the complex printed circuit board of the present invention provides an effective heat-dissipating structure for the high-power electronic elements 30. The depressions 11 or the through holes 11A of the flexible printed wiring board 10 enable the electronic elements 30 to get closer to or directly contact the heat-dissipating substrate 20. Therefore, the heat generated by the electronic elements 30 can be more quickly or directly conducted to the heat-dissipating substrate 20 and dissipated at high efficiency.

The above embodiments are only used to illustrate the present invention, not intended to limit the scope thereof. Many modifications of the above embodiments can be made without departing from the spirit of the present invention.

What is claimed is:

1. A complex printed circuit board structure comprising a flexible printed wiring board and a heat-dissipating substrate bonded with the flexible printed wiring board, electronic elements being electrically connectable with the flexible printed wiring board, parts of surface material of the flexible printed wiring board being removed to form at least one depression for laying the electronic elements therein.

2. The complex printed circuit board structure as claimed in claim 1, wherein the depression is a through hole perforated through the flexible printed wiring board.

3. The complex printed circuit board structure as claimed in claim 1, wherein the depression of the flexible printed wiring board is such formed as to permit the surface of the electronic element to at least partially get closer to or contact the heat-dissipating substrate through the depression.

4. The complex printed circuit board structure as claimed in claim 2, wherein the depression of the flexible printed wiring board is such formed as to permit the surface of the electronic element to at least partially get closer to or contact the heat-dissipating substrate through the depression.

5. The complex printed circuit board structure as claimed in claim 1, wherein after the flexible printed wiring board is bonded with the heat-dissipating substrate, the depression forms an open area on the heat-dissipating substrate.

6. The complex printed circuit board structure as claimed in claim 2, wherein after the flexible printed wiring board is bonded with the heat-dissipating substrate, the depression forms an open area on the heat-dissipating substrate.

7. The complex printed circuit board structure as claimed in claim 1, wherein heat pipes are arranged in the heat-dissipating substrate.

8. The complex printed circuit board structure as claimed in claim 2, wherein heat pipes are arranged in the heat-dissipating substrate.

9. The complex printed circuit board structure as claimed in claim 3, wherein heat pipes are arranged in the heat-dissipating substrate.

10. The complex printed circuit board structure as claimed in claim 4, wherein heat pipes are arranged in the heat-dissipating substrate.

11. The complex printed circuit board structure as claimed in claim 1, wherein the heat-dissipating substrate has an arced pattern.

12. The complex printed circuit board structure as claimed in claim 2, wherein the heat-dissipating substrate has an arced pattern.

13. The complex printed circuit board structure as claimed in claim 3, wherein the heat-dissipating substrate has an arced pattern.

14. The complex printed circuit board structure as claimed in claim 5, wherein the heat-dissipating substrate has an arced pattern.

15. The complex printed circuit board structure as claimed in claim 7, wherein the heat-dissipating substrate has an arced pattern.

16. The complex printed circuit board structure as claimed in claim 1, wherein the heat-dissipating substrate has a cylindrical pattern.

17. The complex printed circuit board structure as claimed in claim 2, wherein the heat-dissipating substrate has a cylindrical pattern.

18. The complex printed circuit board structure as claimed in claim 3, wherein the heat-dissipating substrate has a cylindrical pattern.

19. The complex printed circuit board structure as claimed in claim 5, wherein the heat-dissipating substrate has a cylindrical pattern.

20. The complex printed circuit board structure as claimed in claim 7, wherein the heat-dissipating substrate has a cylindrical pattern.

21. The complex printed circuit board structure as claimed in claim 7, wherein the heat pipes are side by side arranged in the heat-dissipating substrate.

22. The complex printed circuit board structure as claimed in claim 8, wherein the heat pipes are side by side arranged in the heat-dissipating substrate.

23. The complex printed circuit board structure as claimed in claim 9, wherein the heat pipes are side by side arranged in the heat-dissipating substrate.

24. The complex printed circuit board structure as claimed in claim 10, wherein the heat pipes are side by side arranged in the heat-dissipating substrate.

25. The complex printed circuit board structure as claimed in claim 11, wherein the heat pipes are side by side arranged in the heat-dissipating substrate.

26. The complex printed circuit board structure as claimed in claim 12, wherein the heat pipes are side by side arranged in the heat-dissipating substrate.

27. The complex printed circuit board structure as claimed in claim 16, wherein the heat pipes are side by side arranged in the heat-dissipating substrate.

28. The complex printed circuit board structure as claimed in claim 17, wherein the heat pipes are side by side arranged in the heat-dissipating substrate.
